(19) United States
(12) Patent Application Publication
(10) Pub. No.: US 2013/0207085 A1
(43) Pub. Date: Aug. 15, 2013

(54) ORGANIC LIGHT EMITTING DIODE DISPLAY AND METHOD FOR MANUFACTURING THE SAME

(71) Applicant: SAMSUNG DISPLAY CO., LTD., (US)

(72) Inventors: Ja-Hyun Im, Yongin-si (KR); Ji-Hoon Seo, Yongin-si (KR); Beom-Seok Kim, Yongin-si (KR)

(73) Assignee: SAMSUNG DISPLAY CO., LTD., Yongin-si (KR)

(21) Appl. No.: 13/674,697

(22) Filed: Nov. 12, 2012

(30) Foreign Application Priority Data
Feb. 14, 2012 (KR) 10-2012-0014557

(51) Int. Cl. H01L 51/54; H01L 51/56; H01L 33/08

(52) U.S. Cl. 257/40; 257/89; 438/34; 257/E51.026; 257/E33.062

(57) ABSTRACT

An organic light emitting diode display includes a common light emitting layer that can simplify the manufacturing process and prevent infiltration of a light emitting material to an adjacent pixel. The organic light emitting diode display has different light emitting layers disposed above and below the common light emitting layer.

### CROSS-REFERENCE TO RELATED APPLICATIONS

This application claims the benefit of and priority to Korean Patent Application No. 10-2012-0014557, filed on Feb. 14, 2012 in the Korean Intellectual Property Office, the entire content of which is incorporated herein by reference.

### TECHNICAL FIELD

The present disclosure relates to an organic light emitting diode display and a method for manufacturing the same. More particularly, the present disclosure is related to an organic light emitting diode display including a common light emitting layer, and a method for manufacturing the same.

### BACKGROUND

Organic light emitting diode displays are a self-luminous display devices that use organic light emitting diodes to emit light and display images. Unlike liquid crystal displays, organic light emitting diode displays do not require separate light sources, and thus thickness and weight can be reduced. Moreover, organic light emitting diode displays exhibit high quality characteristics such as low power consumption, high luminance, high response speeds, and the like, and thus are being highlighted as next generation display devices for portable electronic apparatuses.

An organic light emitting diode display generally includes a plurality of light emitting layers that include materials for emitting red light, green light, and blue light, respectively. One method for forming the light emitting layers is a deposition process using separate fine metal masks (FMMs) for each of the light emitting layers. However, this complicated deposition process requires using a fine metal mask several times in order to obtain the desired light emitting layers.

Further, in the deposition process using a fine metal mask, when the light emitting material for forming the light emitting layers infiltrates another pixel adjacent to the pixel being subjected to deposition, pixel defects may occur, such as light emission in conjunction with light emission of the adjacent pixel. Such an issue is noticeable in a pentile structure, which is a structure like RGBG and is greatly influenced by adjacent cells.

### SUMMARY

Embodiments of the present disclosure provide an organic light emitting diode display capable of reducing the number of times a deposition process using a fine metal mask is performed in the process for manufacturing the organic light emitting diode display.

Embodiments of the present disclosure provide an organic light emitting diode display (OLED) capable of reducing the defect rate due to undesirable infiltration of a light emitting material to other pixels. Particularly, embodiments of the present disclosure provide an organic light emitting diode display capable of reducing the defect rate due to infiltration of a light emitting material in an OLED having a pentile structure in which pixels are disposed close to each other.

Embodiments of the present disclosure provide a method for manufacturing the organic light emitting diode display.

In an exemplary embodiment of the present disclosure, an organic light emitting diode display includes: a substrate; a plurality of pixel electrodes on the substrate in a matrix pattern; an organic light emitting layer on the pixel electrodes; and a common electrode on the organic light emitting layer. The plurality of pixel electrodes includes a first pixel electrode, a second pixel electrode, and a third pixel electrode. Among the pixel electrodes, a (4n−3)-th pixel electrode, a (4n−1)-th pixel electrode, and a 2n-th pixel electrode in a row direction are the first pixel electrode, second pixel electrode, and third pixel electrode, respectively (where n is a natural number). The organic light emitting layer includes a first light emitting layer, a second light emitting layer, and a third light emitting layer. The first light emitting layer is formed on the first pixel electrode. The second light emitting layer is formed on the first pixel electrode, the second pixel electrode, and the third pixel electrode. The third light emitting layer is formed on the third pixel electrode.

According to an exemplary embodiment of the present disclosure, the first light emitting layer may be disposed beneath the second light emitting layer on the first pixel electrode, and the third light emitting layer may be disposed on the second light emitting layer above the third pixel electrode.

According to another exemplary embodiment of the present disclosure, the first light emitting layer may be disposed on the second light emitting layer above the first pixel electrode, and the third light emitting layer may be disposed beneath the second light emitting layer on the third pixel electrode.

According to an exemplary embodiment of the present disclosure, each of the first light emitting layer and the third light emitting layer may be any one of a red light emitting layer and a green light emitting layer.

According to an exemplary embodiment of the present disclosure, the second light emitting layer may be a blue light emitting layer.

According to an exemplary embodiment of the present disclosure, a p-doped layer may be formed between the third light emitting layer and the second light emitting layer. Here, the p-doped layer may include any one of hexanitrile hexaazatriphenylene, tetrafluoro-tetracyanoquinodimethane (F₄-TCNQ), lithium quinolate (LiQ), FeCl₃, F₁₆CuPc, vanadium oxide (V₂O₅), rhenium oxide (Re₂O₇), indium tin oxide (ITO), or a compound represented by the following Formula 1.

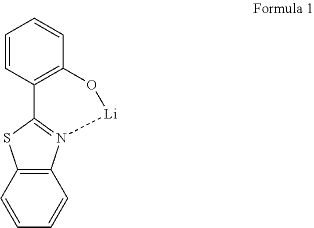

According to an exemplary embodiment of the present disclosure, an electron blocking layer may be formed between the third light emitting layer and the second light emitting layer.

According to an exemplary embodiment of the present disclosure, the second light emitting layer may emit light in a region where the second light emitting layer overlaps with the second pixel electrode.

According to an exemplary embodiment of the present disclosure, the second light emitting layer may not emit light in a region where the second light emitting layer overlaps with the first pixel electrode and the third pixel electrode.

According to an exemplary embodiment of the present disclosure, the plurality of pixel electrodes may be divided into pixel units by a pixel defining layer.

According to an exemplary embodiment of the present disclosure, a first light emitting auxiliary layer may be formed between the pixel electrodes and the organic light emitting layer.

According to an exemplary embodiment of the present disclosure, the first light emitting auxiliary layer may be at least one of a hole injection layer and a hole transporting layer.

According to an exemplary embodiment of the present disclosure, a second light emitting auxiliary layer may be formed between the organic light emitting layer and the common electrode.

According to an exemplary embodiment of the present disclosure, the second light emitting auxiliary layer may be at least one of an electron transporting layer and an electron injection layer.

According to an exemplary embodiment of the present disclosure, the pixel electrodes may define a positive electrode and the common electrode may be a negative electrode.

According to an exemplary embodiment of the present disclosure, among the pixel electrodes, the first pixel electrode and the second pixel electrode may be alternately arranged in a column direction.

According to an exemplary embodiment of the present disclosure, the third pixel electrodes may be arranged successively in a column direction.

According to an exemplary embodiment of the present disclosure, spacers may be disposed between the pixel electrodes.

According to an exemplary embodiment of the present disclosure, spacers may be disposed between the pixel electrodes arranged in the column direction.

According to an exemplary embodiment of the present disclosure, the common electrode may have light transmitting properties.

In another exemplary embodiment of the present disclosure, a method for manufacturing the organic light emitting diode display includes: forming a plurality of pixel electrodes in a matrix pattern on a substrate; forming an organic light emitting layer on the pixel electrodes; and forming a common electrode on the organic light emitting layer. The forming of the pixel electrodes includes forming a first pixel electrode, a second pixel electrode, and a third pixel electrode in which the first pixel electrode, the second pixel electrode, and the third pixel electrode are formed at a (4n−3)-th position, a (4n−1)-th position, and a 2n-th position in a row direction (where n is a natural number). The forming of the organic light emitting layer includes forming a first light emitting layer, forming a second light emitting layer, and forming a third light emitting layer. The first light emitting layer is formed on the first pixel electrode. The second light emitting layer is formed on the first pixel electrode, the second pixel electrode, and the third pixel electrode. The third light emitting layer is formed on the third pixel electrode.

According to an exemplary embodiment of the present disclosure, the first light emitting layer may be formed beneath the second light emitting layer on the first pixel electrode, and the third light emitting layer may be formed on the second light emitting layer above the third pixel electrode.

According to another exemplary embodiment of the present disclosure, the first light emitting layer may be formed on the second light emitting layer above the first pixel electrode, and the third light emitting layer may be formed beneath the second light emitting layer on the third pixel electrode.

According to an exemplary embodiment of the present disclosure, each of the first light emitting layer and the third light emitting layer may be any one of a red light emitting layer or a green light emitting layer.

According to an exemplary embodiment of the present disclosure, the second light emitting layer may be a blue light emitting layer.

According to an exemplary embodiment of the present disclosure, a p-doped layer may be formed between the third light emitting layer and the second light emitting layer. Here, the p-doped layer may include any one of hexanitrile hexaazatriphenylene, tetrafluoro-tetracyanoquinodimethane (F₄-TCNQ), lithium quinolate (LiQ), FeCl₃, F₁₆CuPc, vanadium oxide (V₂O₅), rhenium oxide (Re₂O₇), indium tin oxide (ITO), or a compound represented by the following Formula 1.

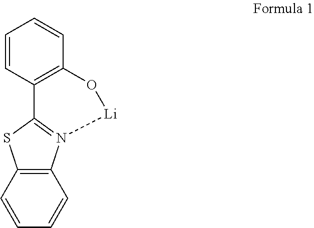

According to an exemplary embodiment of the present disclosure, an electron blocking layer may be formed between the third light emitting layer and the second light emitting layer.

According to an exemplary embodiment of the present disclosure, the second light emitting layer may emit light in a region where the second light emitting layer overlaps the second pixel electrode.

According to an exemplary embodiment of the present disclosure, the second light emitting layer may not emit light in a region where the second light emitting layer overlaps the first pixel electrode and the third pixel electrode.

According to an exemplary embodiment of the present disclosure, the plurality of pixel electrodes may be divided into pixel units by a pixel defining layer.

According to an exemplary embodiment of the present disclosure, a first light emitting auxiliary layer may be formed between the pixel electrodes and the organic light emitting layer.

According to an exemplary embodiment of the present disclosure, the first light emitting auxiliary layer may be at least one of a hole injection layer or a hole transporting layer.

According to an exemplary embodiment of the present disclosure, a second light emitting auxiliary layer may be formed between the organic light emitting layer and the common electrode.

According to an exemplary embodiment of the present disclosure, the second light emitting auxiliary layer may be at least one of an electron transporting layer or an electron injection layer.

According to an exemplary embodiment of the present disclosure, the pixel electrodes may define a positive electrode and the common electrode may be a negative electrode.

According to an exemplary embodiment of the present disclosure, among the pixel electrodes, the first pixel electrode and the second pixel electrode may be alternately arranged in a column direction.

According to an exemplary embodiment of the present disclosure, the third pixel electrodes may be arranged successively in a column direction.

According to an exemplary embodiment of the present disclosure, spacers may be disposed between the pixel electrodes.

According to an exemplary embodiment of the present disclosure, spacers may be disposed between the pixel electrodes arranged in the column direction.

According to an exemplary embodiment of the present disclosure, the common electrode may have light transmitting properties.

In yet another exemplary embodiment of the present disclosure, an organic light emitting diode display includes: a substrate; a plurality of pixel electrodes arranged in a matrix pattern on the substrate; an organic light emitting layer on the pixel electrodes; and a common electrode on the organic light emitting layer. The plurality of pixel electrodes includes a first pixel electrode, a second pixel electrode, and a third pixel electrode. Among the pixel electrodes, a (4n−3)-th pixel electrode, a (4n−1)-th pixel electrode, and a 2n-th pixel electrode in a row direction are the first pixel electrode, the second pixel electrode, and the third pixel electrode, respectively (where n is a natural number). The organic light emitting layer includes a red light emitting layer, a blue light emitting layer, and a green light emitting layer. The red light emitting layer is formed on the first pixel electrode. The blue light emitting layer is formed on the first pixel electrode, the second pixel electrode, and the third pixel electrode. The green light emitting layer is formed on the third pixel electrode. Any one of the red light emitting layer and the green light emitting layer is formed beneath the blue light emitting layer, and the other is formed on the blue light emitting layer.

According to an exemplary embodiment of the present disclosure, the red light emitting layer may be formed between the blue light emitting layer and the first pixel electrode, and the green light emitting layer may be formed between the blue light emitting layer and the common electrode.

The organic light emitting diode display according to exemplary embodiments of the present disclosure can reduce the defect rate due to infiltration to other pixels by including a common light emitting layer.

Further, the method for manufacturing an organic light emitting diode display according to exemplary embodiments of the present disclosure can reduce the number of times a deposition process using a fine metal mask is performed by forming a common light emitting layer.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional view of an organic light emitting diode display according to an exemplary embodiment of the present disclosure.

FIG. 2 is a plan view of an organic light emitting diode display according to an exemplary embodiment of the present disclosure.

FIG. 3 is a plan view of an organic light emitting diode display according to another exemplary embodiment of the present disclosure.

FIG. 4 is a cross-sectional view of an organic light emitting diode display according to yet another exemplary embodiment of the present disclosure.

FIGS. 5A to 5E are cross-sectional views or an organic light emitting diode display at different points in a method for manufacturing an organic light emitting diode display according to an exemplary embodiment of the present disclosure.

### DETAILED DESCRIPTION

Hereinafter, exemplary embodiments of the present disclosure will be described with reference to the accompanying drawings.

While certain exemplary embodiments of the present disclosure are described and illustrated, it is understood that the described embodiments may be modified in various ways without departing from the spirit and scope of the disclosure. Accordingly, the scope of the present disclosure is not limited to the specific exemplary embodiments, and instead should be construed as including all the changes, equivalents, and substitutions included in the spirit and scope of the present disclosure.

The terms used herein are general terms that are know in the art. In some cases, however, terms selected at the applicant's discretion are also used, and for those terms, their meanings should be understood as consistent with the description and use in this detailed description of the present disclosure.

In order to further the understanding of the present disclosure, parts that do not relate to the description are omitted, and like reference numerals designate like elements throughout the specification. Further, in the drawings, the size and the thickness of each element are arbitrarily represented for ease of description, and the present disclosure is not limited to what is shown in the drawings.

In the drawings, the thicknesses of layers, films, panels, regions, etc., are exaggerated for clarity. Further, in the drawings, the thickness of some layers, films, panels, regions, etc., are exaggerated for ease of description. It will be understood that when an element such as a layer, film, region, or substrate is referred to as being “on” another element, it can be directly on the other element or intervening elements may also be present.

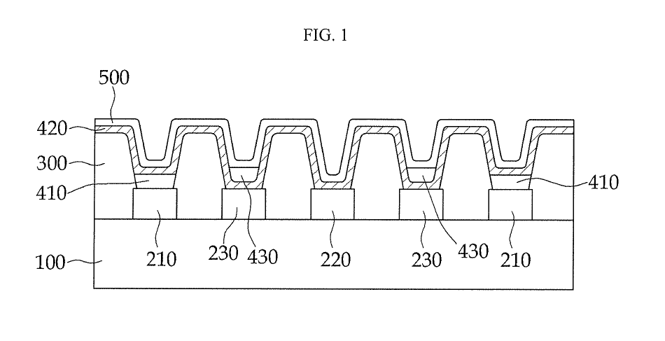

FIG. 1 is a cross-sectional view of an organic light emitting diode display according to an exemplary embodiment of the present disclosure.

Referring to FIG. 1, the organic light emitting diode display may include a substrate 100, a plurality of pixel electrodes including first, second and third pixel electrodes 210, 220, and 230, a pixel defining layer 300, first, second and third light emitting layers 410, 420, and 430, and a common electrode 500.

Although not shown in FIG. 1, the substrate 100 may include an insulating layer and a driving element layer disposed on the insulating layer. The insulating layer may be formed of a transparent insulating substrate made of glass, quartz, ceramic, plastic, or the like. The insulating layer may be a flat plate and may be a flexible substrate which can be bent easily by external force.

The driving element layer is disposed on the insulating layer and may include a pixel driver for driving the organic light emitting diode display, and various wirings, such as a data line or the like. The driving element layer may be formed of a single layer or a plurality of layers.

The pixel driver is connected to any one of the first, second or third pixel electrodes 210, 220, and 230 (to be described below) via a through hole and may control current applied to the first, second and third pixel electrodes 210, 220, and 230. A flat insulating layer may be disposed on the driving element layer.

The pixel defining layer 300 is formed on the substrate 100. The pixel defining layer 300 may include a plurality of matrix-shaped openings. Each pixel is defined according to each opening. In other words, respective pixels are separated from each other by the pixel defining layer 300.

The plurality of pixels may include a first pixel, a second pixel, and a third pixel that emit different colors of light. In an exemplary embodiment, the first pixel may be an area where red light is emitted, the second pixel may be an area where blue light is emitted, and the third pixel may be an area where green light is emitted.

Each of the pixels includes a pixel electrode, a light emitting layer, and a common electrode. The pixel electrodes are formed on the substrate and are divided into pixels by the pixel defining layer 300. In each of the openings formed by the pixel defining layer 300, any one of the first, second or third pixel electrodes 210, 220, and 230 (to be described below) may be disposed. For example, the first pixel electrode 210, the second pixel electrode 220, and the third pixel electrode 230 may be disposed in an opening defining the first pixel, an opening defining the second pixel, and an opening defining the third pixel, respectively.

The first pixel may further include the first light emitting layer 410 formed on the first pixel electrode 210, and the second light emitting layer 420 formed on the first light emitting layer 410 and the first pixel electrode 210.

The second pixel may further include the second pixel electrode 220 as well as the second light emitting layer 420 formed on the second pixel electrode 220.

The third pixel may further include the second light emitting layer 420 formed on the third pixel electrode, and the third light emitting layer 430 formed on the second light emitting layer and the third pixel electrode 230.

The first, second and third pixel electrodes 210, 220, and 230 are positioned on the substrate 100 and may be connected to a driving drain electrode of the pixel driver via the through hole. The first, second and third pixel electrodes 210, 220, and 230 may be made of a reflective conductive material, a transparent conductive material, a translucent conductive material, or the like.

As the reflective conductive material, lithium (Li), calcium (Ca), lithium fluoride/calcium (LiF/Ca), lithium fluoride/aluminum (LiF/Al), aluminum (Al), silver (Ag), magnesium (Mg), gold (Au), or the like may be used. The first, second and third pixel electrodes 210, 220, and 230 may be made of a transparent conductive material or a translucent conductive material. As the transparent conductive material, materials such as indium tin oxide (ITO), indium zinc oxide (IZO), zinc oxide (ZnO), or indium oxide (In₂O₃) may be used.

As the translucent conductive material, a co-deposition material including one or more of magnesium (Mg) or silver (Ag) may be used, or one or more of magnesium (Mg), silver (Ag), calcium (Ca), lithium (Li), or aluminum (Al) may be used.

The first light emitting layer 410 is disposed on the first pixel electrode 210, and the third light emitting layer 430 is disposed on the third pixel electrode 230. The second light emitting layer 420 is disposed on the first light emitting layer 410, the third light emitting layer 430, the second pixel electrode 220, and the pixel defining layer 300 as a common layer.

Since the second light emitting layer 420 is a common light emitting layer that is disposed on the first light emitting layer 410, the third light emitting layer 430, the second pixel electrode 220, and the pixel defining layer 300 as a common layer, a separate fine metal mask is not required when depositing the second light emitting layer 420, thereby reducing the number of processes using fine metal masks compared to the methods in the related art.

In the first, second and third light emitting layers 410, 420, and 430, holes supplied from the first, second and third pixel electrodes 210, 220, and 230 and electrons supplied from the common electrode 500 combine to form excitons. When the energy level of the excitons changes from the excited state to the ground state, light having a color corresponding to the changed energy level is emitted.

According to exemplary embodiments of the present disclosure, the first light emitting layer 410 includes a material capable of emitting red light, the second light emitting layer 420 includes a material capable of emitting blue light, and the third light emitting layer 430 includes a material capable of emitting green light. According to yet another exemplary embodiment of the present disclosure, the first light emitting layer 410, the second light emitting layer 420, and the third light emitting layer 430 may also include materials for emitting green light, blue light, and red light, respectively.

Hereinafter, an embodiment in which the first light emitting layer, the second light emitting layer, and the third light emitting layer are red, blue, and green, respectively, will be described.

The second light emitting layer 420 may have a highest occupied molecular orbital (HOMO) value higher than that of the first light emitting layer 410 so that holes from the first light emitting layer 410 may not be transported to the second light emitting layer 420. Accordingly, in a region of the second light emitting layer 420 included in the first pixel, holes and electrons do not combine, and thus light may not be emitted.

Similarly, holes are introduced to the third light emitting layer 430 through the second light emitting layer 420, but electrons from the third light emitting layer 430 are prevented from transferring to the second light emitting layer 420 so that the third light emitting layer 430 may emit light, while the second light emitting layer 420 may not emit light.

Therefore, in this exemplary embodiment of the present disclosure, in a region where the second light emitting layer 420 overlaps with the second pixel electrode 220, the second light emitting layer 420 emits light, and in a region where the second light emitting layer 420 overlaps with the first pixel electrode 410 and the third pixel electrode 430, the second light emitting layer 420 does not emit light.

Although not shown, in an exemplary embodiment of the present disclosure, a first light emitting auxiliary layer may be disposed between the first light emitting layer 410 and the first pixel electrode 210, between the second light emitting layer 420 and the second pixel electrode 220, and between the third light emitting layer 430 and the third pixel electrode 230. Here, the first light emitting auxiliary layer may include a hole transporting layer and may further include a hole injection layer between the hole transporting layer and the first, second and third pixel electrodes 121, 122, and 123.

Although not shown, in some exemplary embodiments of the present disclosure, a second light emitting auxiliary layer may be formed between the first, second and third light emitting layers 410, 420, and 430 and the common electrode 500. Here, the second light emitting auxiliary layer may be any one of an electron transporting layer and/or an electron injection layer.

According to an exemplary embodiment of the present disclosure, hole blocking layers may be included between the first, second and third light emitting layers 410, 420, and 430 and the common electrode 500. However, the hole blocking layer between the first light emitting layer 410 and the common electrode 500 may be omitted if the second light emitting layer 420 has a HOMO value higher than that of the first light emitting layer 410. According to another exemplary embodiment of the present disclosure, electron blocking layers may be formed between the first, second and third light emitting layers 410, 420, and 430 and the first, second and third pixel electrodes 210, 220, and 230. For example, an electron blocking layer may be formed between the second light emitting layer 420 and the third light emitting layer 430 that are formed on the third pixel electrode 230.

The common electrode 500 is formed on the light emitting layer, and a potential difference may be generated between the common electrode 500 and the first, second and third pixel electrodes 210, 220 and 230 due to an electric potential applied to the common electrode. Specifically, the common electrode is formed on the second light emitting layer 420 and the third light emitting layer 430.

In an exemplary embodiment of the present disclosure, the common electrode 500 may be made of a light transmitting material. In other exemplary embodiments, the common electrode 500 may also be made of a reflective conductive material, a transparent conductive material, or a translucent conductive material.

As the reflective conductive material, lithium (Li), calcium (Ca), lithium fluoride/calcium (LiF/Ca), lithium fluoride/aluminum (LiF/Al), aluminum (Al), silver (Ag), magnesium (Mg), gold (Au), or the like may be used. In a top emission type OLED, the common electrode 500 is made of a transparent conductive material or a translucent conductive material having light transmitting properties. As the transparent conductive material, materials such as indium tin oxide (ITO), indium zinc oxide (IZO), zinc oxide (ZnO), or Indium Oxide (In₂O₃) may be used.

As the translucent conductive material, a co-deposition material including one or more of magnesium (Mg) and/or silver (Ag) may be used, or one or more of magnesium (Mg), silver (Ag), calcium (Ca), lithium (Li), and/or aluminum (Al) may be used.

Although not shown, a glass cap may be disposed on the common electrode 500 opposite the substrate 100. The glass cap serves to seal the first light emitting layer 410, the second light emitting layer 420, or the third light emitting layer 430 (formed between the substrate 100 and the glass cap) from external air. For this configuration, embodiments of the present disclosure may further include a sealing member (not shown) for bonding and sealing the substrate 100 and the glass cap. As the sealing member (not shown), one or more of an acryl-based resin, a methacryl-based resin, polyisoprene, a vinyl-based resin, an epoxy-based resin, a urethane-based resin, and/or a cellulose-based resin may be used.

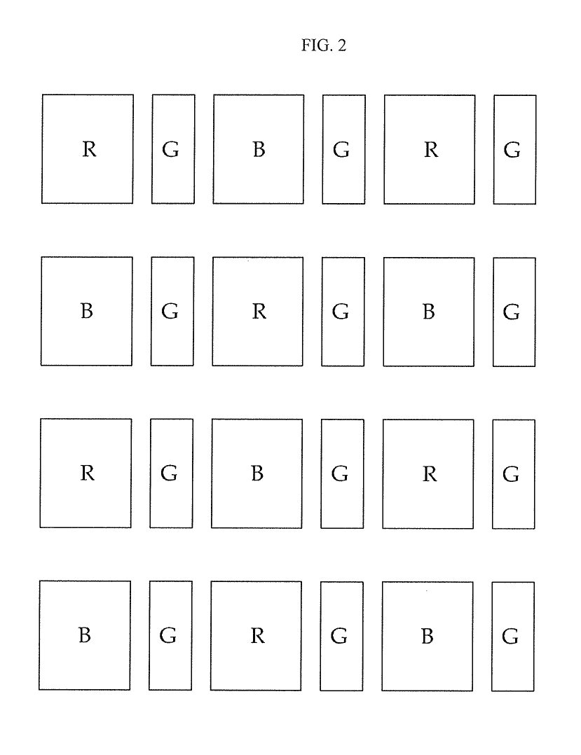

FIG. 2 is a plan view of a plurality of pixel electrodes of the organic light emitting diode display according to an exemplary embodiment of the present disclosure. The electrode arrangement shown in FIG. 2 is referred to as an electrode array arranged in a matrix pattern.

In FIG. 2, the direction from left to right is called a row direction, and the direction from top to bottom is called a column direction.

Among the plurality of pixel electrodes, a (4n−3)-th pixel electrode, a (4n−1)-th pixel electrode, and a 2n-th pixel electrode in a row direction are the first pixel electrode, the second pixel electrode, and the third pixel electrode (where n is a natural number), respectively. In FIG. 2, the first pixel electrode is a red light emitting unit represented by R, the second pixel electrode is a blue light emitting unit represented by B, and the third pixel electrode is a green light emitting unit represented by G.

Pixel electrodes in a row direction are repetitively arranged in the order of R-G-B-G.

In the column direction, R and B are alternately arranged like R-B-R-B at odd-numbered columns, and G is successively arranged at even-numbered columns.

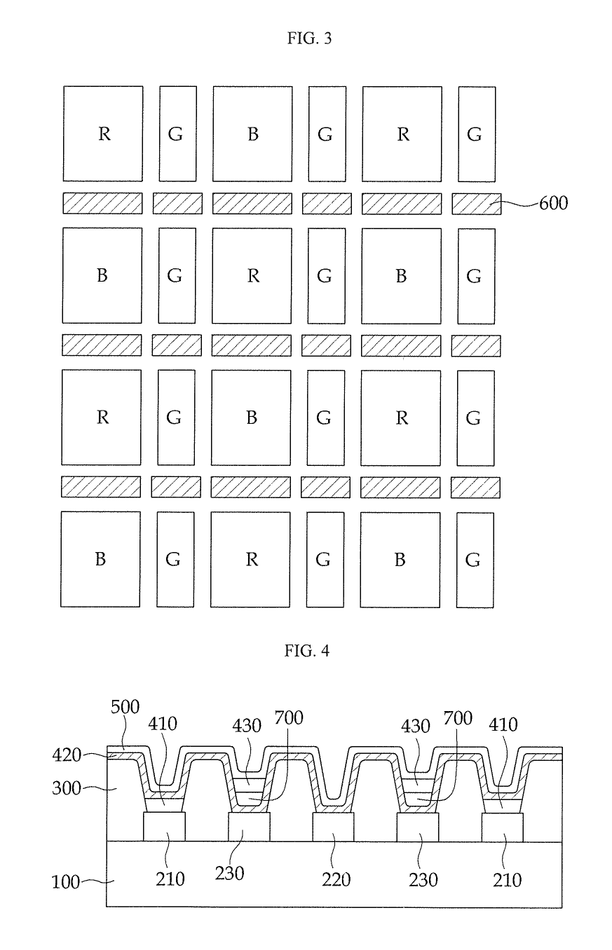

FIG. 3 is a plan view of an organic light emitting diode display according to another exemplary embodiment of the present disclosure.

Referring to FIG. 3, the organic light emitting diode display according to another exemplary embodiment of the present disclosure further includes spacers 600 in the organic light emitting diode display shown in FIG. 1.

The spacers 600 may be deposited between the pixel electrodes in the column direction, that is, between the first pixel electrode 210 and the second pixel electrode 220, and between the third pixel electrodes 230. The spacer 600 is made of an insulating material.

The spacer 600 may be formed inside or at an upper part of the pixel defining layer 300. The pixel defining layer 300 and the spacer 600 may be integrally formed using a photosensitive material by photolithography or by photolithography and etching. In other words, the exposure amount may be adjusted by a halftone exposure process to form the pixel defining layer 300 and the spacer 600 together. However, the present disclosure is not limited thereto, and the pixel defining layer 300 and the spacer 600 may be formed sequentially or separately, and may also be independent structures made of different materials.

In the organic light emitting diode display according to an exemplary embodiment, the spacers 600 are disposed between the pixel electrodes in the column direction to form a higher barrier compared to when only the pixel defining layer 300 exists between the adjacent pixel electrodes in the column direction. This reduces infiltration of a light emitting material to adjacent pixels, thereby reducing the pixel defect rate.

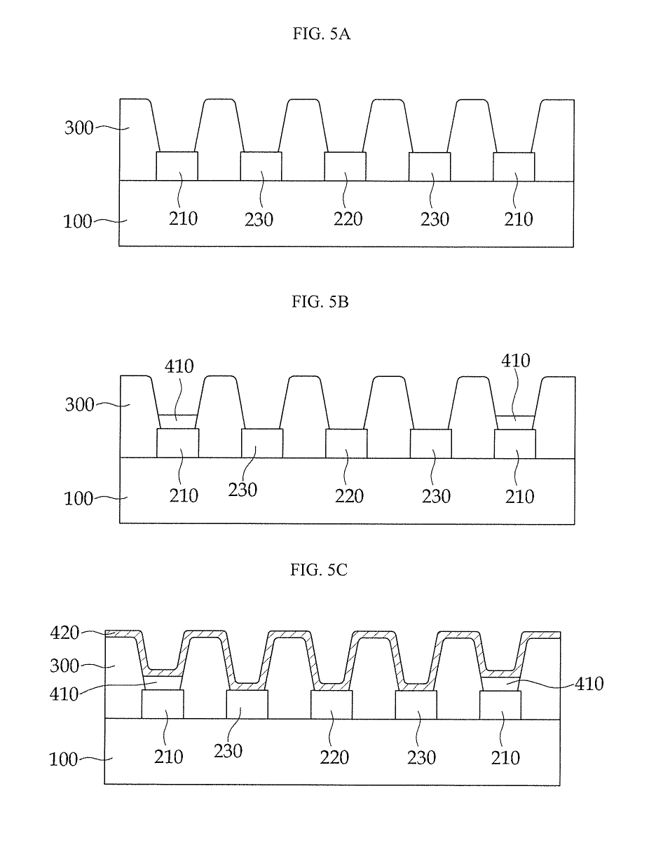

FIG. 4 is a cross-sectional view of an organic light emitting diode display according to yet another exemplary embodiment of the present disclosure.

The organic light emitting diode display shown in FIG. 4 further includes p-doped layers 700 in the organic light emitting diode display shown in FIG. 1.

The p-doped layers 700 may be disposed at the position of the first light emitting auxiliary layer, that is, between a pixel electrode and the organic light emitting layer, and may also be disposed between the second light emitting layer 420 and the third light emitting layer 430, as shown in the exemplary embodiment shown in FIG. 4.

The p-doped layers 700 may be formed using materials and methods that are generally used for forming a p-doped layer. The material of the p-doped layer may include a charge generating material, for example, hexanitrile hexaazatriphenylene, tetrafluoro-tetracyanoquinodimethane (F₄-TCNQ), lithium quinolate (LiQ), FeCl₃, F₁₆CuPc, a compound represented by the following Formula 1, or the like, and may also include a metal oxide such as vanadium oxide (V₂O₅), rhenium oxide (Re₂O₇), indium tin oxide (ITO), or the like.

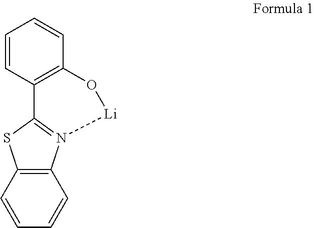

However, the present disclosure is not limited thereto, and a separate layer may be disposed instead of the p-doped layer 700.

In the organic light emitting diode display according to an exemplary embodiment, the p-doped layer 700 is disposed between the second light emitting layer 420 and the third light emitting layer 430. This reduces driving voltage and increases electric field compared to when the p-doped layer is absent, and the second light emitting layer 420 as a common light emitting layer is prevented from emitting light in the third pixel, thereby further reducing the pixel defect rate. The p-doped layer 700 may serve as an electron blocking layer between the second light emitting layer 420 and the third light emitting layer 430. As a result, it is possible to prevent light emission of the second light emitting layer 420 disposed on the third pixel electrode 230.

More details of the organic light emitting diode display according to some exemplary embodiments of the present disclosure described above and other various exemplary embodiments will now be described in connection with a method for manufacturing an organic light emitting diode display according to exemplary embodiments of the present disclosure.

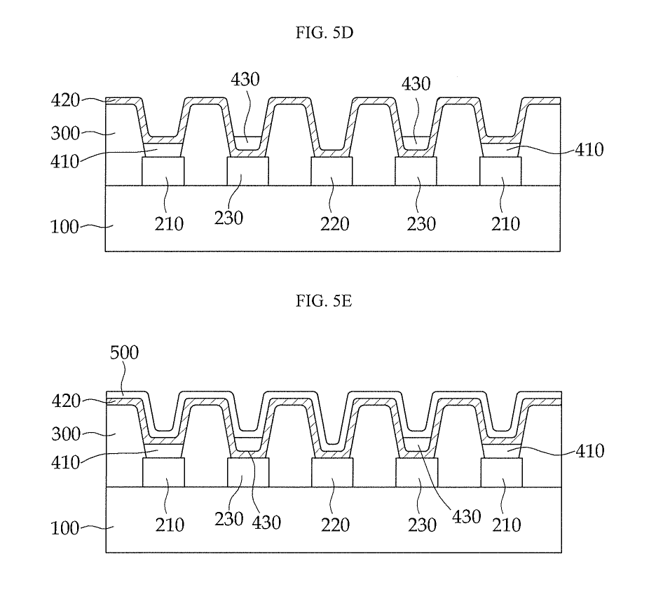

FIGS. 5A to 5E are cross-sectional views of organic light emitting diode displays at various steps of a method for manufacturing an organic light emitting diode display according to an exemplary embodiment of the present disclosure. These figures illustrate a representative method for manufacturing an organic light emitting diode display according to an exemplary embodiment of the present disclosure.

First, a substrate 100 is prepared. The preparing of the substrate 100 may include forming a pixel driver included in a driving element layer on an insulating substrate.

Then, referring to FIG. 5A, a pixel defining layer 300 including a plurality of openings disposed in a matrix pattern is formed on the first substrate 100. According to other exemplary embodiments of the present disclosure, the method may further include a forming a spacer at an upper part of the pixel defining layer 300.

Then, first, second and third pixel electrodes 210, 220, and 230 are formed in the plurality of openings of the pixel defining layer 300. The first pixel electrode 210 may be adjacent to the third pixel electrodes 230 at both sides in a row direction, and may be adjacent to the second pixel electrodes 220 in a column direction. The second pixel electrode 220 may be adjacent to the third pixel electrodes 230 at both sides in a row direction, and may be adjacent to the first pixel electrodes 210 in a column direction. The third pixel electrode 230 may be disposed adjacent to the first pixel electrode 210 at one side in a row direction, and adjacent to the second pixel electrode 220 at the other side, and adjacent to the third pixel electrodes 230 at both sides in a column direction.

Then, referring to FIG. 5B, first light emitting layers 410 are formed by a deposition process. The first light emitting layers 410 may be formed by a deposition process using a separate fine metal mask.

Then, referring to FIG. 5C, a second light emitting layer 420 is formed on the first light emitting layers 410 as a common layer. The second light emitting layer 420 may be formed as a common light emitting layer by being deposited on the entire surface without using a fine metal mask.

Then, referring to FIG. 5D, third light emitting layers 430 are formed by a deposition process. The third light emitting layers 430 may be formed by a deposition process using a fine metal mask.

Then, referring to FIG. 5E, a common electrode 500 is formed on the second light emitting layer 420 and the third light emitting layers 430 as a common layer.

Although not shown, in some exemplary embodiments of the present disclosure, a glass cap may be disposed on the common electrode. The glass cap may be disposed on the common electrode 500 opposite the substrate 100. The disposing of the glass cap may include sealing and coupling the substrate 100 and the glass cap using a sealing member (not shown) to block the first light emitting layer 410, the second light emitting layer 420, or the third light emitting layer 430 from external air.

While various exemplary embodiments of the present disclosure have been described, the present disclosure is not limited to the described embodiments as it is understood that various modifications may be made to the described embodiments without departing from the scope and spirit of the present disclosure, as indicated by the following claims.

What is claimed is:

1. An organic light emitting diode display, comprising:
a substrate;
a plurality of pixel electrodes on the substrate in a matrix pattern, the plurality of pixel electrodes including a first pixel electrode, a second pixel electrode, and a third pixel electrode, where the first pixel electrode is a (4n−3)-th pixel electrode in a row direction, the second pixel electrode is a (4n−1)-th pixel electrode in a row direction, and the third pixel electrode is a 2n-th pixel electrode in a row direction, where n is a natural number;
an organic light emitting layer on the pixel electrodes, the organic light emitting layer including a first light emitting layer, a second light emitting layer, and a third light emitting layer, where the first light emitting layer is on the first pixel electrode, the second light emitting layer is on the first pixel electrode, the second pixel electrode, and the third pixel electrode, and the third light emitting layer is on the third pixel electrode; and
a common electrode on the organic light emitting layer.

2. The organic light emitting diode display of claim 1, wherein the first light emitting layer is beneath the second light emitting layer on the first pixel electrode, and the third light emitting layer is on the second light emitting layer above the third pixel electrode.

3. The organic light emitting diode display of claim 1, wherein the first light emitting layer is on the second light emitting layer above the first pixel electrode, and the third light emitting layer is beneath the second light emitting layer on the third pixel electrode.

4. The organic light emitting diode display of claim 1, wherein each of the first light emitting layer and the third light emitting layer is any one of a red light emitting layer or a green light emitting layer.

5. The organic light emitting diode display of claim 1, wherein the second light emitting layer is a blue light emitting layer.

6. The organic light emitting diode display of claim 2, further comprising a p-doped layer between the third light emitting layer and the second light emitting layer.

7. The organic light emitting diode display of claim 2, further comprising an electron blocking layer between the third light emitting layer and the second light emitting layer.

8. The organic light emitting diode display of claim 6, wherein the p-doped layer includes any one of hexanitrile hexaazatriphenylene, tetrafluoro-tetracyanoquinodimethane (F₄-TCNQ), lithium quinolate (LiQ), FeCl₃, F₁₆CuPc, vanadium oxide (V₂O₅), rhenium oxide (Re₂O₇), indium tin oxide (ITO), or a compound represented by Formula 1:

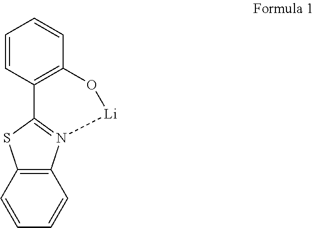

9. The organic light emitting diode display of claim 1, wherein the second light emitting layer emits light in a region where the second light emitting layer overlaps with the second pixel electrode.

10. The organic light emitting diode display of claim 1, wherein the second light emitting layer does not emit light in a region where the second light emitting layer overlaps with the first pixel electrode and the third pixel electrode.

11. The organic light emitting diode display of claim 1, wherein the plurality of pixel electrodes are divided into pixel units by a pixel defining layer.

12. The organic light emitting diode display of claim 1, further comprising a first light emitting auxiliary layer between the pixel electrodes and the organic light emitting layer.

13. The organic light emitting diode display of claim 12, wherein the first light emitting auxiliary layer is at least one of a hole injection layer or a hole transporting layer.

14. The organic light emitting diode display of claim 1, further comprising a second light emitting auxiliary layer between the organic light emitting layer and the common electrode.

15. The organic light emitting diode display of claim 14, wherein the second light emitting auxiliary layer is at least one of an electron transporting layer and an electron injection layer.

16. The organic light emitting diode display of claim 1, wherein the pixel electrodes define a positive electrode and the common electrode is a negative electrode.

17. The organic light emitting diode display of claim 1, wherein the first pixel electrode and the second pixel electrode are alternately arranged in a column direction.

18. The organic light emitting diode display of claim 1, wherein the third pixel electrode is arranged successively in a column direction.

19. The organic light emitting diode display of claim 1, further comprising spacers between the pixel electrodes.

20. The organic light emitting diode display of claim 1, further comprising spacers between the pixel electrodes arranged in a column direction.

21. The organic light emitting diode display of claim 1, wherein the common electrode has a light transmitting property.

22. A method for manufacturing an organic light emitting diode display, comprising:
forming a plurality of pixel electrodes in a matrix pattern on a substrate, the forming of the pixel electrodes including forming a first pixel electrode at a (4n−3)-th position in a row direction, forming a second pixel electrode at a (4n−1)-th position in the row direction, and forming a third pixel electrode at a 2n-th position in the row direction, where n is a natural number;
forming an organic light emitting layer on the pixel electrodes, the forming of the organic light emitting layer including forming a first light emitting layer, forming a second light emitting layer, and forming a third light emitting layer, where the first light emitting layer is formed on the first pixel electrode, the second light emitting layer is formed on the first pixel electrode, the second pixel electrode, and the third pixel electrode, and the third light emitting layer is formed on the third pixel electrode; and
forming a common electrode on the organic light emitting layer.

23. The method of claim 22, wherein the first light emitting layer is formed beneath the second light emitting layer on the first pixel electrode, and the third light emitting layer is formed on the second light emitting layer above the third pixel electrode.

24. The method of claim 22, wherein the first light emitting layer is formed on the second light emitting layer above the first pixel electrode, and the third light emitting layer is formed beneath the second light emitting layer on the third pixel electrode.

25. The method of claim 22, wherein each of the first light emitting layer and the third light emitting layer is any one of a red light emitting layer or a green light emitting layer.

26. The method of claim 22, wherein the second light emitting layer is a blue light emitting layer.

27. The method of claim 23, further comprising forming a p-doped layer between the third light emitting layer and the second light emitting layer.

28. The method of claim 23, further comprising forming an electron blocking layer between the third light emitting layer and the second light emitting layer.

29. The method of claim 27, wherein the p-doped layer includes any one of hexanitrile hexaazatriphenylene, tetrafluoro-tetracyanoquinodimethane (F₄-TCNQ), lithium quinolate (LiQ), FeCl₃, F₁₆CuPc, vanadium oxide (V₂O₅), rhenium oxide (Re₂O₇), indium tin oxide (ITO), and a compound represented by Formula 1:

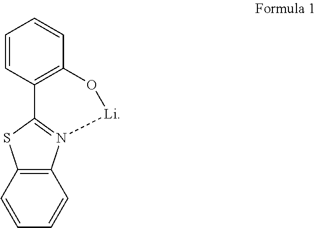

30. The method of claim 22, wherein the second light emitting layer emits light in a region where the second light emitting layer overlaps the second pixel electrode.

31. The method of claim 22, wherein the second light emitting layer does not emit light in a region where the second light emitting layer overlaps the first pixel electrode and the third pixel electrode.

32. The method of claim 22, wherein the plurality of pixel electrodes are divided into pixel units by a pixel defining layer.

33. The method of claim 22, further comprising forming a first light emitting auxiliary layer between the pixel electrodes and the organic light emitting layer.

34. The method of claim 33, wherein the first light emitting auxiliary layer is at least one of a hole injection layer or a hole transporting layer.

35. The method of claim 22, further comprising forming a second light emitting auxiliary layer between the organic light emitting layer and the common electrode.

36. The method of claim 35, wherein the second light emitting auxiliary layer is at least one of an electron transporting layer or an electron injection layer.

37. The method of claim 22, wherein the pixel electrodes define a positive electrode and the common electrode is a negative electrode.

38. The method of claim 22, wherein the first pixel electrode and the second pixel electrode are alternatively arranged in a column direction.

39. The method of claim 22, wherein the third pixel electrodes are arranged successively in a column direction.

40. The method of claim 22, further comprising forming spacers between the pixel electrodes.

41. The method of claim 22, further comprising forming spacers between the pixel electrodes disposed in a column direction.

42. The method of claim 22, wherein the common electrode has a light transmitting property.

43. An organic light emitting diode display, comprising:
a substrate;
a plurality of pixel electrodes in a matrix pattern on the substrate, the plurality of pixel electrodes including a first pixel electrode at a (4n−3)-th position in a row direction, a second pixel electrode at a (4n−1)-th position in the row direction, and a third pixel electrode at a 2n-th position in the row direction, where n is a natural number;
an organic light emitting layer on the pixel electrodes, the organic light emitting layer including a red light emitting layer, a blue light emitting layer, and a green light emitting layer, where the red light emitting layer is on the first pixel electrode, the blue light emitting layer is on the first pixel electrode, the second pixel electrode, and the third pixel electrode, and the green light emitting layer is on the third pixel electrode, and any one of the red light emitting layer and the green light emitting layer is beneath the blue light emitting layer, and the other of the red light emitting layer and the green light emitting layer is on the blue light emitting layer; and
a common electrode on the organic light emitting layer.

44. The organic light emitting diode display of claim 43, wherein the red light emitting layer is between the blue light emitting layer and the first pixel electrode, and the green light emitting layer is between the blue light emitting layer and the common electrode.
